(19) United States
(12) Patent Application Publication
(10) Pub. No.: US 2011/0121259 A1
(43) Pub. Date: May 26, 2011

(54) NITRIDE SEMICONDUCTOR LIGHT EMITTING DEVICE

(76) Inventors: Sang Heon HAN, Suwon (KR); Joo Young CHEON, Suwon (KR); Je Won KIM, Seoul (KR); Dong Ju LEE, Suwon (KR); Dong Chul SHIN, Geojae (KR); Hyun Wook SHIM, Suwon (KR); Jae Woong HAN, Seoul (KR)

(21) Appl. No.: 12/902,233

(22) Filed: Oct. 12, 2010

(30) Foreign Application Priority Data
Nov. 24, 2009 (KR) 10-2009-0113986

(51) Int. Cl. H01L 33/04

(52) U.S. Cl. 257/13; 257/E33.008

(57) ABSTRACT

There is provided a nitride semiconductor light emitting device including an active layer having enhanced external quantum efficiency at both low and high current density. The nitride semiconductor light emitting device includes a first conductivity type nitride semiconductor layer; an active layer disposed on the first conductivity type nitride semiconductor layer and having a plurality of quantum well layers and at least one quantum barrier layer alternately arranged; and a second conductivity type nitride semiconductor layer disposed on the active layer. The plurality of quantum well layers disposed adjacent to each other include first and second quantum well layers having different thicknesses.

### CROSS-REFERENCE TO RELATED APPLICATIONS

This application claims the priority of Korean Patent Application No. 10-2009-0113986 filed on Nov. 24, 2009, in the Korean Intellectual Property Office, the disclosure of which is incorporated herein by reference.

### BACKGROUND OF THE INVENTION

1. Field of the Invention

The present invention relates to a nitride semiconductor light emitting device, and more particularly, to a nitride semiconductor light emitting device including an active layer having enhanced external quantum efficiency at both low and high current density.

2. Description of the Related Art

In recent years, a nitride semiconductor light emitting device produces wide-wavelength-band light including short wavelength light such as blue or green light. A nitride semiconductor light emitting device has come into great prominence in technical fields relevant to a backlight unit (BLU), a lighting device in a vehicle, a general lighting device and the like by broadening an existing market for a display or a portable liquid crystal display.

With many variations in the usage of light emitting devices, current applied thereto is also varied. A light emitting device for a mobile phone has operated at low applied current of approximately 20 mA. However, as the usage of the light emitting device is being expanded into a high-output light emitting device for BLUs and lighting devices, the applied current has been variably distributed from 100 mA to 350 mA or more.

With an increase in current applied to a light emitting device, the current density of the light emitting device also increases. In the case of a nitride semiconductor light emitting device on the basis of InGaN/GaN, as current density applied increases, external quantum efficiency rapidly decreases. This is known as “efficiency droop.”

In order to avoid such an efficiency droop phenomenon, the confinement effect of carriers is increased. Also, an existing light emitting device attempts to enhance external quantum efficiency at high current density by employing an active layer of 10 nm or more or adding indium (In) to a barrier layer in an active layer having a multiple quantum well structure in order to increase the combination of electrons and holes for enhanced luminous efficiency. That is, the increasing of the confinement effect of the carriers allows the electrons and the holes to be confined to a very thin quantum well layer of approximately 2.5 nm to 3 nm, thereby increasing the combination of the electrons and the holes for enhanced luminous efficiency.

However, in the case of an existing light emitting device structure, even though an active layer is formed by using many quantum well layers, light emission only actually occurs in one or two quantum well layers adjacent to the p-GaN region due to the low concentration and low mobility of holes relative to those of electrons in a p-GaN region. This leads to an increase in the concentration of carriers in the quantum well layers in which light emission actually occurs, and accordingly, the possibility of the occurrence of Auger non-radiative recombination increases. With an increase in applied current, the concentration of carriers flowing within a light emitting device generally increases. At this time, since electrons have a higher mobility as compared with holes, the electrons fail to combine with the holes within the quantum well layer, and thus overflow into the p-GaN region. Due to the above-described Auger non-radiative recombination and electron overflow, the efficiency droop phenomenon in which the external quantum efficiency of the light emitting device is sharply reduced at high current density still occurs.

### SUMMARY OF THE INVENTION

An aspect of the present invention provides a nitride semiconductor light emitting device including an active layer having enhanced external quantum efficiency at both low and high current density.

According to an aspect of the present invention, there is provided a nitride semiconductor light emitting device including: a first conductivity type nitride semiconductor layer; an active layer disposed on the first conductivity type nitride semiconductor layer and having a plurality of quantum well layers and at least one quantum barrier layer alternately arranged; and a second conductivity type nitride semiconductor layer disposed on the active layer. The plurality of quantum well layers disposed adjacent to each other include first and second quantum well layers having different thicknesses.

The first and second quantum well layers may emit light of the same wavelength. The first quantum well layer may have an In composition ratio lower than the second quantum well layer. The first quantum well layer may be disposed adjacent to the first conductivity type nitride semiconductor layer, and the second quantum well layer may be disposed adjacent to the second conductivity type nitride semiconductor layer and have a thickness thinner than the first quantum well layer. The first conductivity type nitride semiconductor layer may be an n-type nitride semiconductor layer.

The first quantum well layer may have a thickness of 2 nm to 15 nm and the second quantum well layer may have a thickness of 1 nm to 4 nm.

At least one of the first and second quantum well layers may have an energy band structure including inclined portions. The energy band structure may include inclined portions having any one of triangular-shaped and trapezoidal-shaped structures.

The active layer may have one or more sets, each including the first and second quantum well layers and a first quantum barrier layer disposed therebetween, and include a second quantum barrier layer dividing the sets. The first and second quantum barrier layers may have the same thickness, or the second quantum barrier layer may have a thickness greater than the first quantum barrier layer.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a side cross-sectional view schematically illustrating the structure of a nitride semiconductor light emitting device according to a first exemplary embodiment of the present invention;

FIG. 2 is an energy band diagram illustrating a first example of an active layer of the nitride semiconductor light emitting device according to the first exemplary embodiment of the present invention shown in FIG. 1;

FIG. 3 is an energy band diagram illustrating a second example of an active layer of the nitride semiconductor light emitting device according to the first exemplary embodiment of the present invention shown in FIG. 1;

FIG. 4 is an energy band diagram illustrating a third example of an active layer of the nitride semiconductor light emitting device according to the first exemplary embodiment of the present invention shown in FIG. 1;

FIG. 5 is an energy band diagram illustrating a fourth example of an active layer of the nitride semiconductor light emitting device according to the first exemplary embodiment of the present invention shown in FIG. 1;

FIG. 6 is an energy band diagram illustrating a fifth example of an active layer of the nitride semiconductor light emitting device according to the first exemplary embodiment of the present invention shown in FIG. 1;

FIG. 7 is an energy band diagram illustrating a nitride semiconductor light emitting device according to a second exemplary embodiment of the present invention;

FIG. 8 is an energy band diagram illustrating another example of an active layer of the nitride semiconductor light emitting device according to the second exemplary embodiment of the present invention shown in FIG. 7;

FIG. 9 is a side cross-sectional view schematically illustrating the structure of a nitride semiconductor light emitting device according to a third exemplary embodiment of the present invention;

FIG. 10 is a side cross-sectional view schematically illustrating another example of an active layer of the nitride semiconductor light emitting device according to the third exemplary embodiment of the present invention shown in FIG. 9; and

FIG. 11 is a graph illustrating the comparison of quantum efficiency according to current density between the nitride semiconductor light emitting device according to the first exemplary embodiment of the present invention and a nitride semiconductor light emitting device according to the related art.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

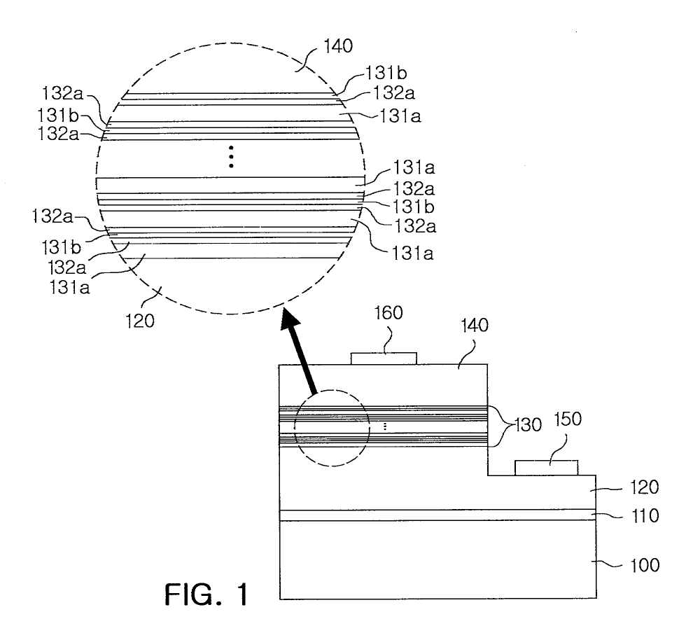

FIG. 1 is a side cross-sectional view schematically illustrating the structure of a nitride semiconductor light emitting device according to a first exemplary embodiment of the present invention.

As shown in FIG. 1, a nitride semiconductor light emitting device includes a substrate 100, and a buffer layer 110, an n-type nitride semiconductor layer 120, an active layer 130, and a p-type nitride semiconductor layer 140 that are sequentially stacked on the substrate 100. Also, an n-electrode 150 and a p-electrode 160 are formed on the mesa-etched n-type nitride semiconductor layer 120 and the p-type nitride semiconductor layer 140, respectively. Here, the positions of the n-type and p-type nitride semiconductor layers 120 and 140 may be exchanged with each other.

As for the substrate 100, a sapphire substrate may be used as a growth substrate in order to grow a nitride semiconductor layer. The sapphire substrate is made of a crystal having Hexa-Rhombo (R3c) type symmetry and has lattice constants of 13.001 Å and 4.758 Å in the directions of a C-axis and an A-axis, respectively. The sapphire substrate includes a C-plane (0001), an A-plane (1120), an R-plane (1102), or the like. Since the C-plane (0001) is advantageous to the growth of a nitride thin film and is stable at high temperatures, it is primarily used as a substrate for nitride growth. However, the substrate 100 is not limited to the sapphire substrate. The substrate 100 may be formed of SiC, Si, GaN, AlN or the like.

The buffer layer 110 is provided so as to relieve lattice mismatch between the substrate 100 and the n-type nitride semiconductor layer 120. This buffer layer 110 may be a low temperature nucleus growth layer including AlN or GaN.

The n-type and p-type nitride semiconductor layers 120 and 140 may have a composition represented by AlₓIn_{y}Ga₍₁₋ₓ₋y)N where 0≦x≦1, 0≦y≦1, and 0≦x+y≦1 are satisfied. The n-type and p-type nitride semiconductor layers 120 and 140 may be formed of semiconductor materials doped with n-type and p-type dopants, respectively. Representative examples of the semiconductor materials may include GaN, AlGaN and InGaN. The n-type dopants may utilize Si, Ge, Se, Te or C, and the p-type dopants may utilize Mg, Zn or Be. The n-type and p-type nitride semiconductor layers 120 and 140 may be grown by use of a known process, such as metal organic chemical vapor deposition (MOCVD), molecular beam epitaxy (MBE) or hydride vapor phase epitaxy (HVPE).

The active layer 130 has a multiple quantum well structure in which a plurality of quantum well layers and at least one quantum barrier layer are alternately arranged, so that electron-hole recombination occurs so as to emit light. The plurality of quantum well layers disposed adjacent to each other include first and second quantum well layers 131a and 131b having different thicknesses. The first quantum well layer 131a has a thickness greater than the second quantum well layer 131b. Here, the wavelengths of light emitted through the first and second quantum well layers 131a and 131b are identical to each other. In order to achieve the same wavelength of emitted light, the two quantum well layers 131a and 131b have a different composition ratio of indium (In) in such a manner that the first quantum well layer 131a has an In composition ratio lower than the second quantum well layer 131b. This allows the relatively thin second quantum well layer 131b to have the same quantum potential as the first quantum well layer 131a, whereby the two quantum well layers may emit light of the same wavelength. Here, the first quantum well layer 131a may have a thickness of 2 nm to 15 nm and the second quantum well layer may have a thickness of 1 nm to 4 nm.

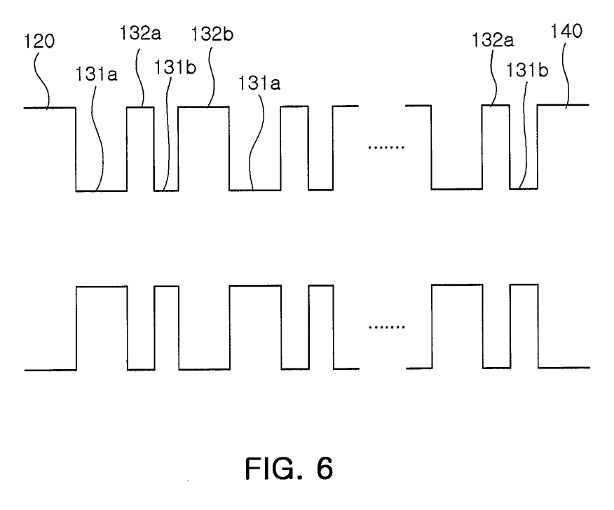

This active layer 130 may have a multiple quantum well structure in which the two quantum well layers 131a and 131b having a first quantum barrier layer 132a disposed therebetween are repeatedly arranged. That is, the active layer 130 may have a multilayer set structure, in which each set includes the two quantum well layers 131a and 131b having different thicknesses and the first quantum barrier layer 132a disposed therebetween and is divided from an adjacent set by the first quantum barrier layer 132a. Here, the first quantum barrier layer 132a may be a superlattice layer having a thickness allowing for the tunneling of holes injected from the p-type nitride semiconductor layer 140. The quantum barrier layer may be represented by AlₓIn_{y}Ga_{(1-x-y)}N where 0≦x≦1, 0<y≦1, and 0<x+y≦1 are satisfied. The quantum well layers may be represented by In_{z}Ga_{(1-z)}N where 0≦z≦1 is satisfied. Also, the active layer 130 may have the multilayer set structure in which each set may be divided from an adjacent set by a second quantum barrier layer (not shown) thicker than the first quantum barrier layer 132a. This will be described in detail with reference to FIG. 6 later.

As described above, since the active layer 130 has the multiple quantum well structure, when a low density current is applied, light emission primarily occurs at the relatively thin second quantum well layer 131b, and when a high density current is applied, holes are injected into the relatively thick first quantum well layer 131a and light emission occurs at the first quantum well layer 131a as well as the second quantum well layer 131b. Here, since the first quantum well layer 131a having a thickness greater than the second quantum well layer 131b has a large volume, the concentration of carriers in unit volume is reduced to thereby prevent a reduction in luminous efficiency induced by Auger non-radiative recombination occurred at the high current density.

As the first quantum barrier layer 132a between the first quantum well layer 131a and the second quantum well layer 131b becomes thinner, hole injection from the second quantum well layer 131b to the first quantum well layer 131a may be facilitated and the injection efficiency of electrons through the tunneling of the electrons from the first quantum well layer 131a to the second quantum well layer 131b may also be enhanced.

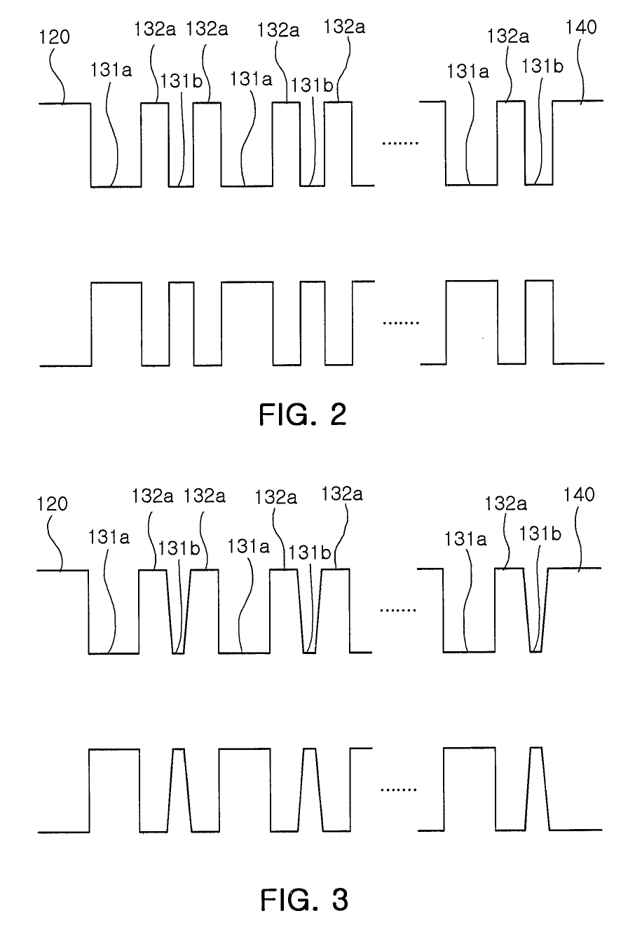

FIG. 2 is an energy band diagram illustrating a first example of an active layer of the nitride semiconductor light emitting device according to the first exemplary embodiment of the present invention shown in FIG. 1. As shown in FIG. 2, in the active layer 130 of the nitride semiconductor light emitting device, the first quantum well layer 131a is disposed adjacent to the n-type nitride semiconductor layer 120 and the second quantum well layer 131b is disposed adjacent to the p-type nitride semiconductor layer 140. These first and second quantum well layers 131a and 131b may have a rectangular energy band structure. The second quantum well layer 131b is thinner than the first quantum well layer 131a. The second quantum well layer 131b has an In composition ratio higher than the first quantum well layer 131a. Accordingly, the first and second quantum well layers 131a and 131b may emit light of the same wavelength.

FIGS. 3 through 5 illustrate examples of a variety of energy band structures of first and second quantum well layers in an active layer of the nitride semiconductor light emitting device according to the first exemplary embodiment of the present invention. In this nitride semiconductor light emitting device according to the present invention, the first quantum well layer 131a is disposed adjacent to the n-type nitride semiconductor layer 120 and the second quantum well layer 131b is disposed adjacent to the p-type nitride semiconductor layer 140.

FIG. 3 is an energy band diagram illustrating a second example of an active layer of the nitride semiconductor light emitting device according to the first exemplary embodiment of the present invention shown in FIG. 1.

As shown in FIG. 3, the first quantum well layer 131a may have a rectangular energy band structure and the second quantum well layer 131b may have a trapezoidal energy band structure. The trapezoidal energy band structure of the second quantum well layer 131b is formed by increasing the In component by gradually increasing the amount of In source material injected into the second quantum well layer 131b or reducing growth temperature, maintaining the increasing of the In component for a predetermined time, and then reducing the In component by gradually reducing the amount of In source material injected into the second quantum well layer 131b or increasing growth temperature. Here, the second quantum well layer 131b has an In composition ratio higher than the first quantum well layer 131a.

In the structure of the active layer as described above, the first quantum well layer 131a having the rectangular energy band structure is disposed adjacent to the n-type nitride semiconductor layer 120 and the second quantum well layer 131b having the trapezoidal energy band structure is disposed adjacent to the p-type nitride semiconductor layer 140. The trapezoidal energy band structure of the second quantum well layer 131b alleviates a potential barrier caused by a piezoelectric effect between a quantum well layer and a quantum barrier layer with respect to holes passing from the second quantum well layer 131b to the first quantum well layer 131a, whereby hole injection may be efficiently performed.

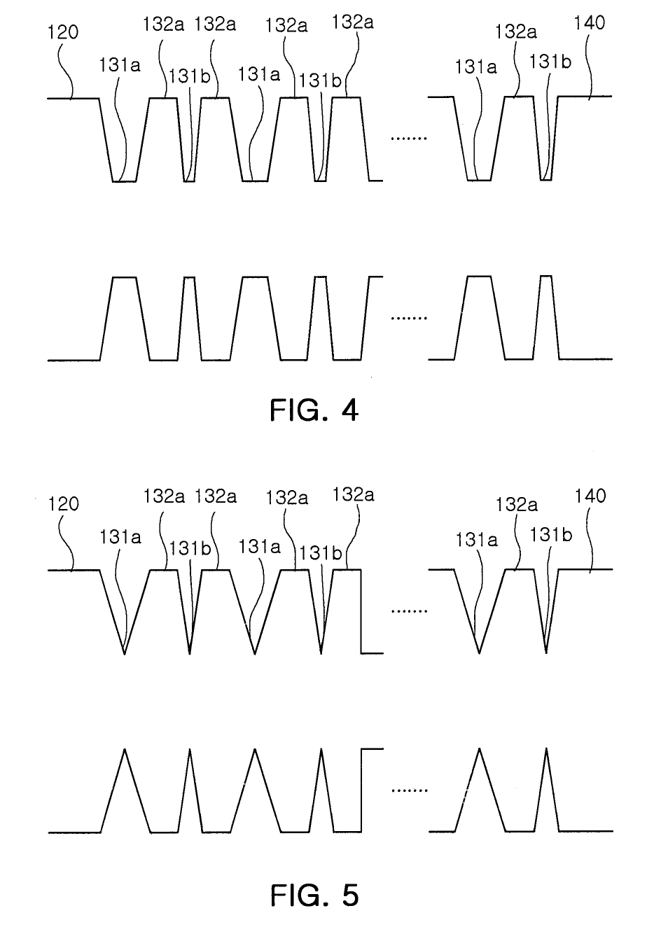

FIG. 4 is an energy band diagram illustrating a third example of an active layer of the nitride semiconductor light emitting device according to the first exemplary embodiment of the present invention shown in FIG. 1. As shown in FIG. 4, the first and second quantum well layers 131a and 131b may have a trapezoidal energy band structure. This trapezoidal energy band structure is identical to that of FIG. 3, so a detailed description thereof will be omitted.

FIG. 5 is an energy band diagram illustrating a fourth example of an active layer of the nitride semiconductor light emitting device according to the first exemplary embodiment of the present invention shown in FIG. 1. As shown in FIG. 5, the first and second quantum well layers 131a and 131b may have a triangular energy band structure. This triangular energy band structure is formed by increasing the In component by growing the first and second quantum well layers 131a and 131b while gradually increasing the amount of In source material injected thereinto or reducing growth temperature, and then reducing the In component by growing the first and second quantum well layers 131a and 131b while gradually reducing the amount of In source material or increasing growth temperature.

FIG. 6 is an energy band diagram illustrating a fifth example of an active layer of the nitride semiconductor light emitting device according to the first exemplary embodiment of the present invention shown in FIG. 1. In this exemplary embodiment, the first quantum well layer 131a is disposed adjacent to the n-type nitride semiconductor layer 120, and the second quantum well layer 131b, thinner than the first quantum well layer 131a, is disposed adjacent to the p-type nitride semiconductor layer 140.

As shown in FIG. 6, the active layer 130 according to this exemplary embodiment is formed of the first quantum well layer 131a, the second quantum well layer 131b thinner than the first quantum well layer 131a, and the first quantum barrier layer 132a interposed therebetween that constitute a single set. Each set may be divided from an adjacent set by a second quantum barrier layer 132b thicker than the first quantum barrier layer 132a. When the second quantum barrier layer 132b is thick, the quality of the quantum well layers stacked on the second quantum barrier layer 132b can be improved. Also, the first and second quantum barrier layers 132a and 132b may have the same thickness.

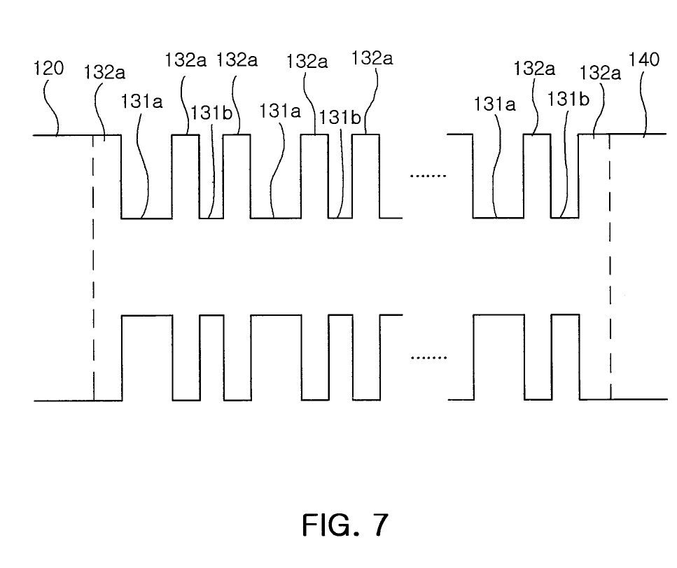

FIG. 7 is an energy band diagram illustrating a nitride semiconductor light emitting device according to a second exemplary embodiment of the present invention. The nitride semiconductor light emitting device according to the second exemplary embodiment shown in FIG. 7 is substantially the same as that according to the first exemplary embodiment shown in FIG. 1, except that it further includes the quantum barrier layer 132a between the n-type and p-type nitride semiconductor layers 120 and 140 and the active layer. Therefore, a detailed description of the same parts as described in the exemplary embodiment of FIG. 1 will be omitted. Only different parts defined in the second exemplary embodiment of FIG. 7 will be described.

As shown in FIG. 7, the nitride semiconductor light emitting device according to the second exemplary embodiment of the invention has a stack structure, in which the quantum barrier layer 132a is first stacked on the n-type nitride semiconductor layer 120; the quantum well layers 131a and 131b and the quantum barrier layer 132a are alternately stacked; and then the quantum barrier layer 132a is lastly stacked. After that, the p-type nitride semiconductor layer 140 is formed on the quantum barrier layer 132a. This structure may prevent the dopants of the n-type and p-type nitride semiconductor layers 120 and 140 from being injected into the active layer.

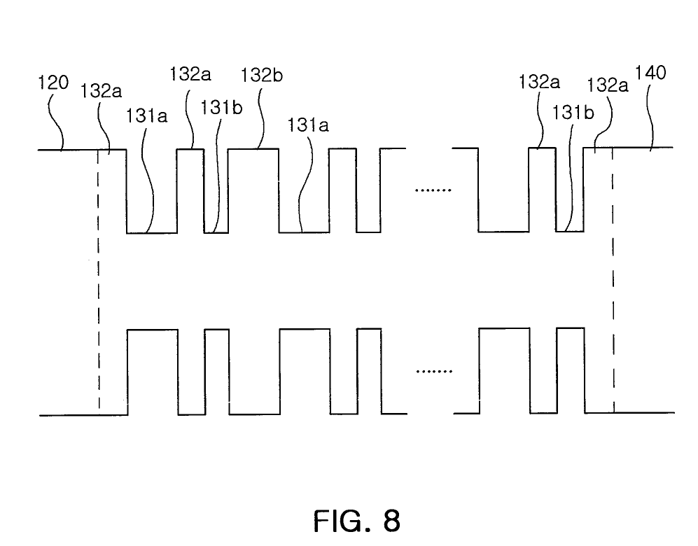

FIG. 8 is an energy band diagram illustrating another example of an active layer of the nitride semiconductor light emitting device according to the second exemplary embodiment of the present invention shown in FIG. 7. As shown in FIG. 8, the active layer is formed of the first quantum well layer 131a, the second quantum well layer 131b thinner than the first quantum well layer 131a, and the first quantum barrier layer 132a interposed therebetween that constitute a single set. Each set may be divided from an adjacent set by the second quantum barrier layer 132b thicker than the first quantum barrier layer 132a. When the second quantum barrier layer 132b is thick, the quality of the quantum well layers stacked on the second quantum barrier layer 132b can be improved.

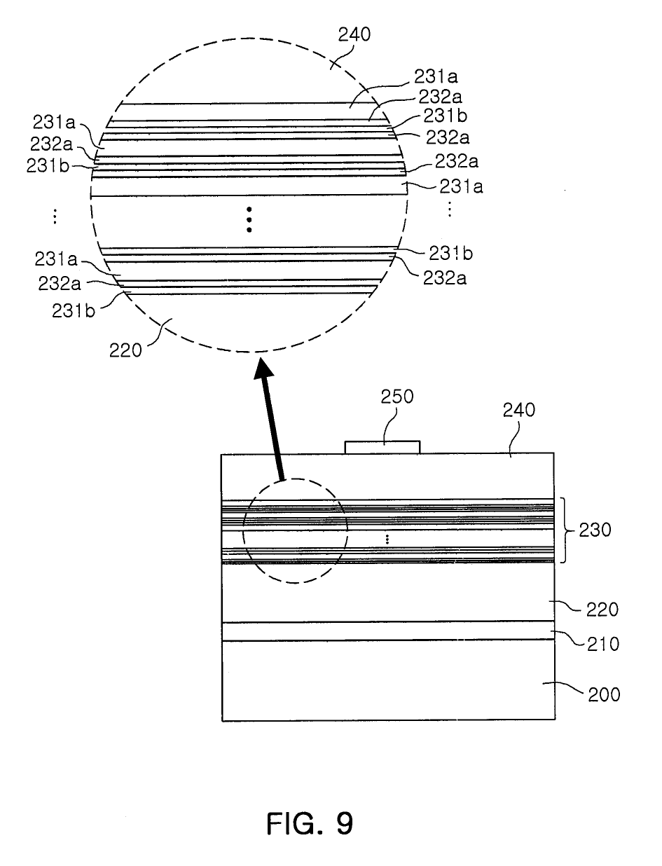

FIG. 9 is a side cross-sectional view schematically illustrating the structure of a nitride semiconductor light emitting device according to a third exemplary embodiment of the present invention. Here, a vertical nitride semiconductor light emitting device is formed such that the substrate 100 of the nitride semiconductor light emitting device shown in FIG. 1 is removed and p-type and n-type electrodes are arranged to face each other in a stacked direction of nitride semiconductor layers.

As shown in FIG. 9, the nitride semiconductor light emitting device according to the third exemplary embodiment of the invention includes a conductive substrate 200, and a highly reflective ohmic contact layer 210, a p-type nitride semiconductor layer 220, an active layer 230 and an n-type nitride semiconductor layer 240 that are stacked on the conductive substrate 200. Here, a stack formed of the p-type nitride semiconductor layer 220, the active layer 230, and the n-type nitride semiconductor layer 240 is defined as a light emitting structure. Further, an n-type electrode 250 is formed on the upper surface of the n-type nitride semiconductor layer 240.

When a process such as the removal of a growth substrate is performed, the conductive substrate 200 may support the relatively thin light emitting structure, be provided as a bonding area to which a printed circuit board (PCB) is bonded by using a conductive adhesive layer, and function as a p-type electrode. This conductive substrate 200 may be bonded to the light emitting structure by plating or wafer bonding. The conductive substrate 200 may be formed of any one of Si, SiAl, SiC, ZnO, GaAs, and GaN.

Although not indispensable, the highly reflective ohmic contact layer 210 has a high level of reflectivity and forms ohmic contact with the p-type nitride semiconductor layer 220. This highly reflective ohmic contact layer 210 may have a reflectivity of 90% or more. For example, the highly reflective ohmic contact layer 210 may be formed of at least one metallic layer selected from the group consisting of Ag, Al, Rh, Ru, Pt, Au, Cu, Pd, Cr, Ni, Co, Ti, In and Mo, or an allow layer thereof. A single metallic or alloy layer or a plurality of metallic or alloy layers may be formed.

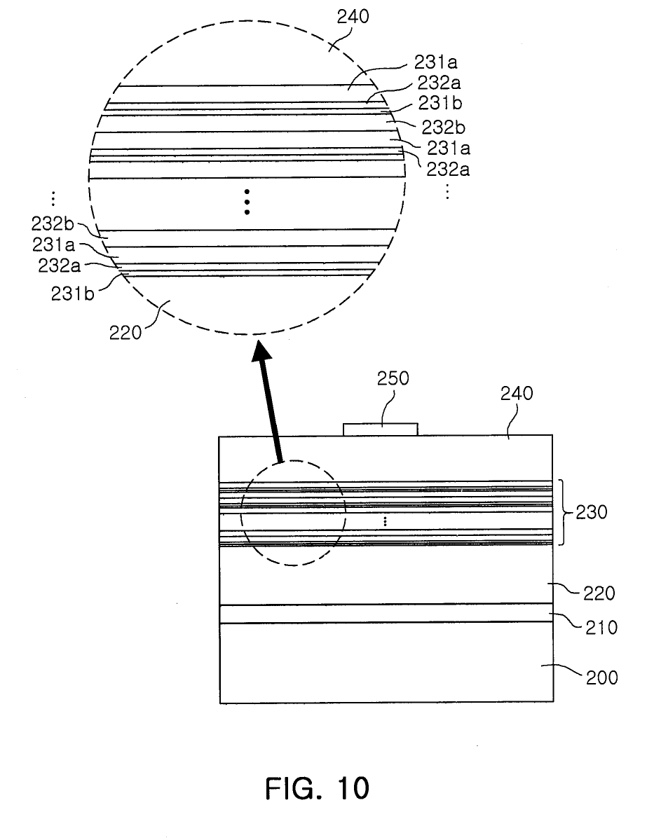

The active layer 230 may have a multiple quantum well structure including a plurality of quantum well layers and at least one quantum barrier layer. Here, the active layer 230 includes first and second quantum well layers 231a and 231b spaced apart from each other by a first quantum barrier layer 232a and having different thicknesses. The first and second quantum well layers 231a and 231b of different thicknesses emit light of the same wavelength. In order to emit light of the same wavelength, the two quantum well layers 231a and 231b have a different composition ratio of In in such a manner that the second quantum well layer 231b, relatively thinner than the first quantum well layer 231a, has an In composition ratio higher than the first quantum well layer 231a. Also, the first quantum barrier layer 232a may be a superlattice layer having a thickness allowing for the tunneling of holes injected from the p-type nitride semiconductor layer 240. Further, the active layer 230 may have a multilayer set structure, in which each set includes the two quantum well layers 231a and 231b and the first quantum barrier layer 232a disposed therebetween and is divided from an adjacent set by a second quantum barrier layer (not shown). A detailed description thereof will be provided with reference to FIG. 10 later.

Therefore, since the active layer 230 has the above-described structure, when a low density current is applied, light emission primarily occurs at the relatively thin second quantum well layer 231b, and when a high density current is applied, holes are injected into the relatively thick first quantum well layer 131a and light emission occurs at the first quantum well layer 131a as well as the second quantum well layer 131b. Here, since the first quantum well layer 131a having a thickness greater than the second quantum well layer 131b has a large volume, the concentration of carriers in unit of volume is reduced to thereby prevent a reduction in luminous efficiency induced by Auger non-radiative recombination occurred at the high current density.

As the first quantum barrier layer 232a between the first quantum well layer 231a and the second quantum well layer 231b becomes thinner, hole injection from the second quantum well layer 131b to the first quantum well layer 131a may be facilitated and the injection efficiency of electrons through the tunneling of the electrons from the first quantum well layer 131a to the second quantum well layer 131b may also be enhanced.

FIG. 10 is a side cross-sectional view schematically illustrating another example of an active layer of the nitride semiconductor light emitting device according to the third exemplary embodiment of the present invention shown in FIG. 9. Here, the nitride semiconductor light emitting device shown in FIG. 10 is substantially the same as that according to the third exemplary embodiment shown in FIG. 9, except that it further includes a second quantum barrier layer 232b formed to be thicker than the first quantum barrier layer 232a. Therefore, a detailed description of the same parts as described in the exemplary embodiment of FIG. 9 will be omitted. Only the different part defined in the third exemplary embodiment of FIG. 10 will be described.

As shown in FIG. 10, the active layer 230 is formed of the first quantum well layer 231a, the second quantum well layer 231b thinner than the first quantum well layer 231a, and the first quantum barrier layer 232a interposed therebetween that constitute a single set. Each set may be divided from an adjacent set by the second quantum barrier layer 232b thicker than the first quantum barrier layer 232a. When the second quantum barrier layer 232b is thick, the quality of the quantum well layers stacked on the second quantum barrier layer 232b can be improved.

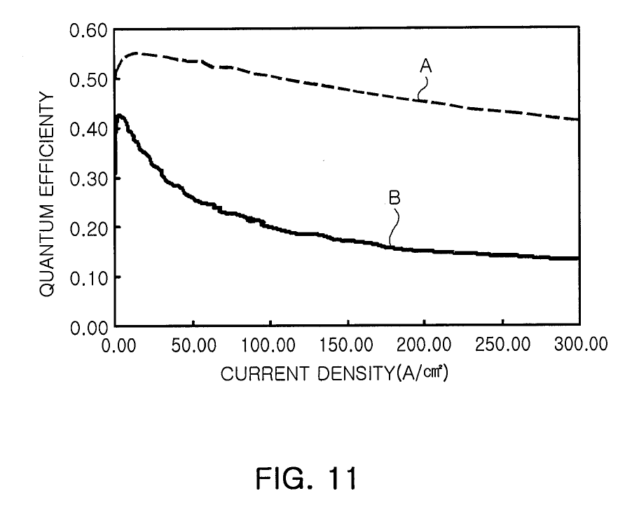

FIG. 11 is a graph illustrating the comparison of quantum efficiency according to current density between the nitride semiconductor light emitting device according to the first exemplary embodiment of the invention and a nitride semiconductor light emitting device according to the related art.

Here, A represents the quantum efficiency of the nitride semiconductor light emitting device according to the first exemplary embodiment of the invention, and B represents the quantum efficiency of the nitride semiconductor light emitting device having a multiple quantum well structure including quantum well layers of the same thickness according to the related art.

As shown in FIG. 11, the nitride semiconductor light emitting device having the multiple quantum well structure according to the related art shows a great reduction of the quantum efficiency B as current density increases. However, the nitride semiconductor light emitting device according to the present invention relieves a reduction of the quantum efficiency A as compared with the quantum efficiency B as a high density current is applied.

As set forth above, in a nitride semiconductor light emitting device according to exemplary embodiments of the invention, when a low density current is applied, external quantum efficiency may be enhanced by using a thin quantum well layer, and when a high density current is applied, external quantum efficiency may be enhanced by reducing the concentration of carriers by using a thick quantum well layer and suppressing non-radiative recombination. Therefore, the nitride semiconductor light emitting device allows for enhanced external quantum efficiency at both low and high current density.

While the present invention has been shown and described in connection with the exemplary embodiments, it will be apparent to those skilled in the art that modifications and variations can be made without departing from the spirit and scope of the invention as defined by the appended claims.

What is claimed is:

1. A nitride semiconductor light emitting device comprising:
a first conductivity type nitride semiconductor layer;
an active layer disposed on the first conductivity type nitride semiconductor layer and having a plurality of quantum well layers and at least one quantum barrier layer alternately arranged; and
a second conductivity type nitride semiconductor layer disposed on the active layer,
wherein the plurality of quantum well layers disposed adjacent to each other include first and second quantum well layers having different thicknesses.

2. The nitride semiconductor light emitting device of claim 1, wherein the first and second quantum well layers emit light of the same wavelength.

3. The nitride semiconductor light emitting device of claim 2, wherein the first quantum well layer has an In composition ratio lower than the second quantum well layer.

4. The nitride semiconductor light emitting device of claim 1, wherein the first quantum well layer is disposed adjacent to the first conductivity type nitride semiconductor layer, and the second quantum well layer is disposed adjacent to the second conductivity type nitride semiconductor layer and has a thickness thinner than the first quantum well layer.

5. The nitride semiconductor light emitting device of claim 4, wherein the first conductivity type nitride semiconductor layer is an n-type nitride semiconductor layer.

6. The nitride semiconductor light emitting device of claim 1, wherein the first quantum well layer has a thickness of 2 nm to 15 nm.

7. The nitride semiconductor light emitting device of claim 1, wherein the second quantum well layer has a thickness of 1 nm to 4 nm.

8. The nitride semiconductor light emitting device of claim 1, wherein at least one of the first and second quantum well layers has an energy band structure including inclined portions.

9. The nitride semiconductor light emitting device of claim 8, wherein the energy band structure includes inclined portions having any one of triangular-shaped and trapezoidal-shaped structures.

10. The nitride semiconductor light emitting device of claim 1, wherein the active layer has one or more sets, each including the first and second quantum well layers and a first quantum barrier layer disposed therebetween and includes a second quantum barrier layer dividing the sets.

11. The nitride semiconductor light emitting device of claim 10, wherein the first and second quantum barrier layers have the same thickness.

12. The nitride semiconductor light emitting device of claim 10, wherein the second quantum barrier layer has a thickness greater than the first quantum barrier layer.
